(19) United States
(12) Patent Application Publication
(10) Pub. No.: US 2026/0342299 A1
(43) Pub. Date: Oct. 29, 2026

(54) RAIL-TO-RAIL FEEDFORWARD COMPENSATED STRUCTURES FOR RECEIVER

(71) Applicant: Silicon Laboratories Inc., Austin, TX (US)

(72) Inventor: Aslamali A. Rafi, Austin, TX (US)

(21) Appl. No.: 19/188,083

(22) Filed: Apr. 24, 2025

(51) Int. Cl. H03F 3/45

(52) U.S. Cl. CPC H03F 3/45475; H03F 2203/45222

(57) ABSTRACT

In one aspect, an apparatus includes: a first operational amplifier (op-amp) having a first feedforward compensation structure, the first op-amp to receive a first current and output a first voltage; and a second op-amp having a second feedforward compensation structure, the second op-amp to receive a second current based on the first voltage and output a second voltage. The first op-amp may operate with a first current consumption and the second op-amp may operate with a second current consumption, the second current consumption lower than the first current consumption.

### BACKGROUND

As wireless technology advances, some protocols operate at extremely high frequencies. For example, for advanced Wi-Fi protocols such as Wi-Fi 5 and 6e, operation is at frequencies between approximately 5-7 gigahertz (GHz). Furthermore, these wireless receivers are often a part of a system-on-chip (SoC) and suffer from various sources of noise and/or interference. Differential architectures are often used for better immunity to interference/noise. However, a differential architecture consumes significant current and degrades battery life. In addition, this differential circuitry increases circuit area, particularly with the presence of a balun. Single-ended architectures offer lower power operation and smaller area, but are more sensitive to noise/interference. A frequency notch circuit can be used to filter interference/noise, but making it tunable over a wide frequency range (5 GHZ-7 GHz for example) makes this approach infeasible.

### SUMMARY OF INVENTION

In one aspect, an apparatus includes: a first operational amplifier (op-amp) having a first feedforward compensation structure, the first op-amp to receive a first current and output a first voltage; and a second op-amp having a second feedforward compensation structure, the second op-amp to receive a second current based on the first voltage and output a second voltage. The first op-amp may operate with a first current consumption and the second op-amp may operate with a second current consumption, the second current consumption lower than the first current consumption.

In one implementation, the first op-amp comprises a transimpedance amplifier (TIA) to receive the first current at a downconverted frequency and to output the first voltage at the downconverted frequency. The apparatus may further include a filter coupled to the TIA, the filter comprising the second op-amp to receive the second current at the downconverted frequency. The filter may be a biquadratic filter further including a third op-amp having a third feedforward compensation structure, the third op-amp to receive a third current based on the second voltage and output a third voltage. The first op-amp may operate with a first noise performance level and the second op-amp may operate with a second noise performance level, the second noise performance level higher than the first noise performance level.

In an implementation, the first op-amp includes: a plurality of transconductors; and at least one feedforward transconductor coupled to at least some of the plurality of transconductors. The at least one feedforward transconductor is to share current with at least one of the plurality of transconductors. The plurality of transconductors may include at least three main path transconductors, and the at least one feedforward transconductor may include a first feedforward transconductor and a second feedforward transconductor. The second feedforward transconductor may be configured to provide compensation to at least one of the three main path transconductors as an output signal swings from a first rail to a second rail.

In another aspect, an apparatus includes: a feedforward compensated op-amp having: a first main path transconductor; a second main path transconductor coupled to the first main path transconductor; and a feedforward path coupled between an input of the first main path transconductor and an output of the second main path transconductor, the feedforward path including at least one feedforward transconductor. At least one of the first main path transconductor and the second main path transconductor may reuse a current from the at least one feedforward transconductor.

In one implementation, the at least one feedforward transconductor is to cancel at least one pole of the first main path transconductor or the second main path transconductor. The feedforward compensated op-amp may be an intermediate frequency (IF) transimpedance amplifier (TIA) to receive an IF current and to output an IF voltage.

In one implementation, the apparatus further includes a filter coupled to the IF TIA. The filter may include: a plurality of main path transconductors; and at least one feedforward transconductor coupled between an input of a first main path transconductor of the plurality of main path transconductors and an output of a last main path transconductor of the plurality of main path transconductors.

In an implementation, the feedforward compensated op-amp further includes: a third main path transconductor coupled between the output of the first main path transconductor and an input of the second main path transconductor; and the at least one feedforward transconductor includes a first feedforward transconductor and a second feedforward transconductor. An output of the second main path transconductor and an output of the second feedforward transconductor may be configured to swing rail-to-rail. The first feedforward transconductor may be configured to share current with at least the third main path transconductor.

In yet another aspect, a method includes: receiving, in a first op-amp having a first feedforward compensation structure and operating with a first current consumption, a first current and outputting a first voltage; and receiving, in a second op-amp having a second feedforward compensation structure and operating with a second current consumption lower than the first current consumption, a second current based on the first voltage and outputting a second voltage.

In one implementation, the method further includes receiving the first current in the first op-amp comprising a TIA at a downconverted frequency and outputting the first voltage at the downconverted frequency. The method may also include filtering the second current at the downconverted frequency, the second op-amp comprising a filter coupled to the TIA. The method may also include receiving, in a third op-amp having a third feedforward compensation structure, a third current based on the second voltage and outputting a third voltage.

### BRIEF DESCRIPTION OF THE DRAWINGS

FIG. 1 is a schematic diagram of a receiver architecture in accordance with an embodiment.

FIG. 2 is a schematic diagram of a bias circuit in accordance with an embodiment.

FIG. 3 is a schematic diagram of a feedforward compensation structure in accordance with an embodiment.

FIG. 4 is a schematic diagram of a feedforward compensation structure in accordance with another embodiment.

FIG. 5 is a schematic diagram of a current reuse operational amplifier in accordance with an embodiment.

FIG. 6 is a graphical illustration of loop gain realized using a feedforward compensated operational amplifier in accordance with an embodiment.

FIG. 7 is a block diagram of a representative integrated circuit in accordance with an embodiment.

FIG. 8 is a high level diagram of a network in accordance with an embodiment.

### DETAILED DESCRIPTION

In various embodiments, a receiver is configured to operate over a wide band of frequencies while providing a single-ended architecture to reduce power consumption and chip area, and at the same time avoiding additional circuitry such as certain front-end filters and balun circuitry. Furthermore, embodiments provide a receiver architecture having multiple transimpedance amplifiers that operate at different frequencies. In some implementations at least one of these transimpedance amplifiers may be implemented using an operational amplifier having a feedforward compensation structure. This structure also may be used in certain filter circuitry to provide desired levels of linearity while at the same time reducing power consumption. These different feedforward compensation structures can be implemented with differently sized devices to trade off power consumption and linearity. Further details will be appreciated in light of the following discussion.

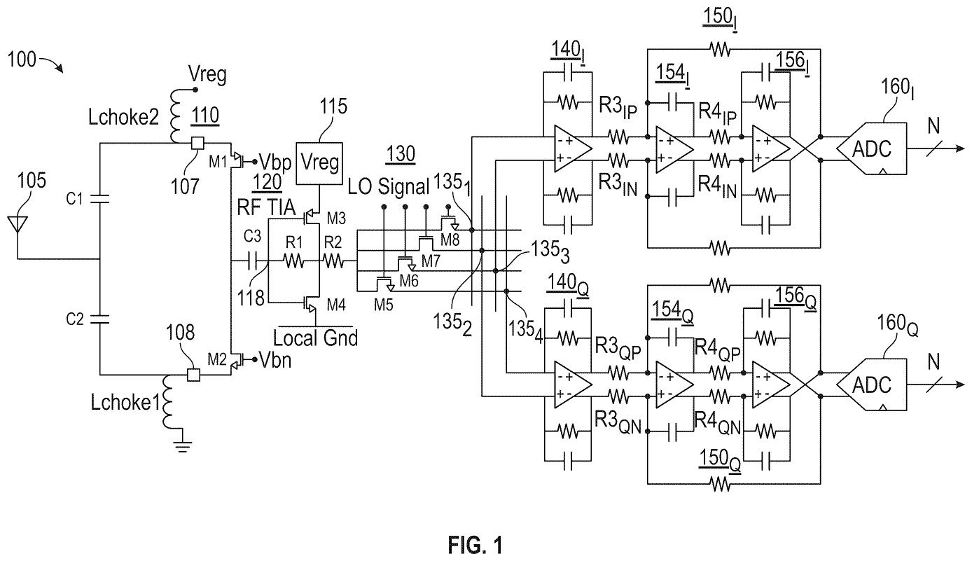

Referring now to FIG. 1, shown is a schematic diagram of a receiver architecture in accordance with an embodiment. In the high-level view of FIG. 1, the majority of circuitry of receiver 100 may be implemented on a single semiconductor die as adapted into a given integrated circuit (IC) package. As shown in FIG. 1, receiver 100 is configured to receive incoming radio frequency (RF) signals and process them along a signal processing path to obtain digitized samples that are then provided to additional processing circuitry, such as a digital signal processor (DSP) (not shown for ease of illustration in FIG. 1).

Incoming RF signals are received via an antenna 105. Antenna 105 is coupled to a pair of capacitors C1 and C2 through which the RF signals are AC coupled. The RF signal thus split is provided to a low noise amplifier (LNA) 110 via a path having shunt-coupled inductances coupled to an input of LNA 110.

More specifically as shown, a first choke inductor (Lchoke 1) couples between a pad 108 of a semiconductor die and a paddle ground. This paddle ground is a lowest ground or reference voltage level of receiver 100, and may be realized as a ground voltage received via a ground voltage node of a printed circuit board to which an IC package including receiver 100 is adapted. In turn, another choke inductor (Lchoke 2), couples between a pad 107 and a voltage regulator node. These choke inductors may be implemented to provide a high impedance to direct the RF signal to LNA 110. While shown in FIG. 1 as being formed of off-chip inductances, in another embodiment these choke inductors may be integrated on the same semiconductor die as the remaining circuitry of receiver 100.

In embodiments, LNA 110 may be implemented as a wideband common gate LNA. Although embodiments are not limited in this regard, LNA 110 may be configured as a current reuse LNA. Although embodiments are not limited in this regard, LNA 110 may be configured to operate over a bandwidth of at least 2 gigahertz (GHz). For example, in one implementation LNA 110 may be configured for wideband operation to accommodate Wi-Fi signals of extended Wi-Fi capabilities (e.g., Wi-Fi 6e and Wi-Fi 7), where RF signals may be in the range of approximately 4.9 GHZ-7.125 GHz. As such, LNA 110 may be configured to operate over a bandwidth where a highest frequency exceeds a lowest frequency by a ratio of at least approximately 1.4×. Of course, other wideband ranges are possible in other implementations. For purposes of discussion herein, the term “wideband” is intended to refer to a bandwidth of at least 1.5 GHz.

Still referring to FIG. 1, the split RF signal couples through pads 107, 108 of a semiconductor die to corresponding metal oxide semiconductor field effect transistors (MOSFETs) M1 and M2 of LNA 110. More specifically, MOSFET M1 is implemented as a p-channel MOSFET (PMOS), and MOSFET M2 is implemented as an n-channel MOSFET (NMOS). As shown, MOSFETs M1, M2 are implemented in a common gate configuration with the incoming RF signal provided to corresponding source terminals of the MOSFETs and amplified RF signals being output via drain terminals of the MOSFETs.

In turn, the gate terminals of MOSFETs M1, M2 are configured to receive corresponding bias voltages Vbp and Vbn, respectively. As will be described further herein, these bias voltages and thus these gate terminals themselves may be decoupled from the noisy chip ground. In an embodiment, a bias circuit having filter circuitry may generate these bias voltages. By maintaining these bias voltages and LNA 110 decoupled from the chip ground, reduced noise is introduced via LNA 110. Via this decoupling, regulator noise may be rejected across the wideband of operation of LNA 110 without requiring presence of a notch filter.

As mentioned above, in some embodiments, LNA 110 may be implemented with a current reuse architecture, reducing power consumption. In this configuration, PMOS device M1 and NMOS device M2 operate using the same current from the power supply. In other words, the current of the PMOS device M1 also flows through and biases NMOS device M2 and hence current is reused. Note depending on implementation, there can be several ways to bias (i.e., generate Vbn and Vbp for) this current reuse structure.

With further reference to FIG. 1, the amplified RF signal output from LNA 110 couples via a capacitor C3 to an RF transimpedance amplifier (TIA) 120 having an input node 118, which may be at a virtual ground level. Note that this virtual ground DC potential is at a different ground level than the paddle ground. The loop gain of RF TIA 120 helps to achieve high linearity without requiring differential circuitry in the receiver front end. Note that the virtual ground impedance at node 118 is low for a large incoming frequency (e.g., up to approximately 10 GHz).

RF TIA 120 is configured to convert an input current of the amplified RF signal to a voltage. As illustrated, RF TIA 120 is implemented with corresponding MOSFETs, namely, a PMOS device M3 and an NMOS device M4. As shown, this RF signal couples to gate terminals of MOSFETs M3, M4 and is output via corresponding drain terminals of the MOSFETS. As further shown, the source terminal of NMOS device M4 couples to a local ground node, which may be at a different ground or reference level than both the paddle ground and another ground level for the bias circuit. In turn, the source terminal of P MOS device M3 couples to a voltage regulator 115. Via resistors R1 and R2, the voltage level output from RF TIA 120 is converted to a current. This current is provided to a mixer 130, which is implemented as a single balanced mixer to downconvert the RF signal to a lower frequency signal. More specifically, mixer 130 can be configured to downconvert the RF signals to an intermediate frequency (IF), which in one example may be approximately 10 megahertz (MHz).

As shown, mixer 130 includes resistor R2 and a plurality of MOSFETS, namely, NMOS devices M5-M8, each of which is coupled to receive, via a gate terminal, a corresponding clock signal, namely a 25 percent duty cycle local oscillator (LO) signal. MOSFETs M5-M8 also have drain terminals to receive the RF current and source terminals to output the downconverted IF current. In this way, mixer 130 is configured to rotatably couple resistor R2 to output nodes 135₁₋₄ of mixer 130. As shown, output nodes 135 couple to corresponding inputs of separate in-phase and quadrature phase (I/Q) paths, each of which is implemented as a differential signal processing path. Resistor R2 also operates to suppress impedance translation effects.

The current of the IF signal couples to inputs (which may be at a different virtual ground level than the input of RF TIA 120, namely an IF virtual ground level) of an IF TIA 140_{I,Q}. As shown in the high-level view of FIG. 1, IF TIA 140 is implemented as an operational amplifier (op-amp). In embodiments as described further herein, these op-amps may be implemented with a feedforward compensation structure, and in particular embodiments can be implemented with a current reuse configuration to reduce power consumption. With this arrangement, a maximum loop gain may be realized at an interfering frequency, while maintaining high linearity. In the illustration of FIG. 1, note the resistive/capacitive feedback structures coupled between the inputs and outputs of the op-amps.

IF TIA 140 is configured to convert the incoming current to a voltage. In turn, resistors R3_{IP-QN} generate currents that are provided to corresponding biquadratic (biquad) filters 150_{I,Q}. As shown, each biquad filter 150 includes a pair of series-coupled op-amps 154_{I}, 156_{I} and 154_{Q}, 156_{Q}. In implementations, these op-amps also may be implemented with feedforward compensated structures. As seen, these series-coupled op-amps have corresponding resistors R4_{IP-QN} coupled therebetween to generate currents.

With embodiments that implement IF TIA 140 and biquad filter 150 using the same feedforward compensation structure, different tradeoffs may be made in design of these different structures for their different use cases in receiver 100.

More specifically, with the configuration in FIG. 1, noise concerns are more relevant for IF TIA 140 than for filter 150. However, linearity concerns are relevant for filter 150. With the implementation in FIG. 1, larger devices (and thus higher-power consuming devices) may be used for the first stage of the feedforward compensation structure of the op-amps of IF TIA 140 than for those present in filter 150. For example, in one implementation MOSFETs of the first stage of IF TIA 140 may be of a first size while those present in filter 150 may be of a second size smaller than the first size. In one example, the first size may be 4× of the second size. For a typical implementation, this approach to sizing results in a reduction of current consumption of filter 150 from 8.5 mA to 3.5 mA without any degradation in performance. Similarly, the current consumption of TIA 140 using this feedforward compensation scheme results in reduction of its current from 4 mA to about 2 mA. This represents a savings of at least 2× in current in the analog baseband chain, increasing battery life. In some implementations, op-amps 154, 156 also may be differently sized, with op-amp 154 having larger-sized MOSFETs than those for op-amp 156. In other implementations, MOSFETs of op-amps 154 and 156 may be of the same size.

Still referring to FIG. 1, the resulting filtered IF signals in turn are provided to a digitizer, namely an analog-to-digital converter (ADC) 160_{I,Q}. In an embodiment, ADC 160 may be implemented as a successive approximation (SAR) ADC to provide an N-bit output that can be further processed digitally.

With an arrangement such as illustrated in FIG. 1, reduced power consumption may be realized, owing to the single-ended arrangement of LNA 110. In addition, by way of the single-ended configuration, the circuit area and power consumption of an on-chip balun and a notch filter can be avoided. Although shown at this high level in the embodiment of FIG. 1, many variations and alternatives are possible.

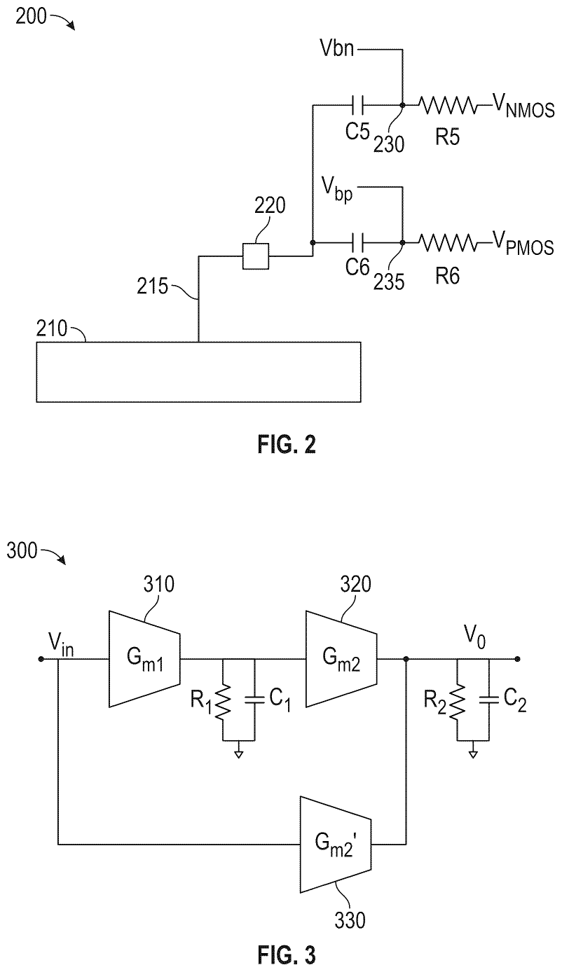

As described above, regulator noise may be rejected by providing bias circuitry that generates bias voltages for LNA 110 in a decoupled manner from the rest of the chip and coupled to the clean paddle ground. Referring now to FIG. 2, shown is a schematic diagram of a bias circuit in accordance with an embodiment. As shown in FIG. 2, bias circuit 200 is configured to generate bias voltages to be provided to the gate terminals of the MOSFETs of a single-ended common gate LNA as described herein.

As shown, bias circuit 200 is configured to be decoupled from the rest of the chip and instead coupled to a clean paddle ground 210. As shown, bias circuit 200 couples to a pad 220 of a semiconductor die. Pad 220 is coupled to paddle ground 210 via a bond wire 215, which may be a dedicated bond wire only to couple these components together.

Bias circuit 200 is implemented with filter circuitry, namely RC filters, shown as series-coupled resistors and capacitors, namely series-coupled devices C5/R5 and C6/R6. These filter circuits thus decouple the bias voltages (V_{bn} and V_{bp}) obtained at inter-device nodes 230, 235, from paddle ground 210. Note that the voltages coupled to resistors R5, R6 (V_{NMOS} and V_{PMOS}) may be provided from additional bias circuitry not shown for ease of illustration. Also, understand that other implementations of a bias circuit including filter circuitry may be realized.

As discussed above, an IF TIA and biquad filter can be implemented using op-amps, more specifically, op-amps having a feedforward compensation structure. Referring now to FIG. 3, shown is a schematic diagram of a feedforward compensation structure in accordance with an embodiment. As shown, in FIG. 3, circuit 300 may be implemented as an op-amp. As shown, a main path includes a first transconductor 310 (Gₘ₁) and a second transconductor 320 (Gₘ₂). As further shown, RC circuits are coupled in shunt at the outputs of these transconductors (namely, parallel-coupled resistor R₁, C₁ and R₂, C₂). In some implementations, these RC circuits may be implemented as parasitics. For example, R1 and R2 could be from the output impedance of the transistors in the Gₘ stages. However, understand that certain intentional resistors/capacitors may be present.

To provide feedforward compensation, a feedforward path is present and couples between an input of first transconductor 310 and an output of second transconductor 320. Thus as shown, a feedforward transconductor 330 (G_{m2′}) is provided. Feedforward transconductor 330 introduces a zero, which cancels the pole of first transconductor 310. This zero introduced at a unity gain frequency (UGF) of first transconductor 310 may be scaled by a ratio between the feedforward transconductor and the second main path transconductor, namely, G_{m2′}/Gₘ₂.

With the configuration shown in FIG. 3, the following transfer functions may be realized:

$$\frac{{v}_{o}}{{v}_{in}} = ( \frac{{G}_{m 1} {R}_{1}}{( 1 + {sR}_{1} {C}_{1} )} {G}_{m 2} + {G}_{m 2}^{′} ) \frac{{R}_{2}}{( 1 + {sR}_{2} {C}_{2} )}$$

$$\frac{{v}_{o}}{{v}_{in}} \sim ( \frac{1 + s / {ω}_{z}}{1 + {sR}_{1} {C}_{1}} ) \frac{{G}_{m 1} {G}_{m 2} {R}_{1} {R}_{2}}{( 1 + {sR}_{2} {C}_{2} )}$$

$${ω}_{z} = \frac{{G}_{m 1}}{{C}_{1}} ( \frac{{G}_{m 2}^{′}}{{G}_{m 2}} ) = {ω}_{ugf 1} ( \frac{{G}_{m 2}^{′}}{{G}_{m 2}} )$$

In contrast, without a feedforward path in accordance with an embodiment, the transfer function would be:

$$\frac{{v}_{o}}{{v}_{in}} = \frac{{G}_{m 1} {R}_{1}}{( 1 + {sR}_{1} {C}_{1} )} \frac{{G}_{m 2} {R}_{2}}{( 1 + {sR}_{2} {C}_{2} )} .$$

And thus with an embodiment, the zero introduced at the UGF of first transconductor 310 scales by the ratio of the additional transconductors. In essence, by providing this feedforward compensation structure, linearity is maintained, even when trading off power consumption. Although shown at this high level in the embodiment of FIG. 3, variations and alternatives are possible.

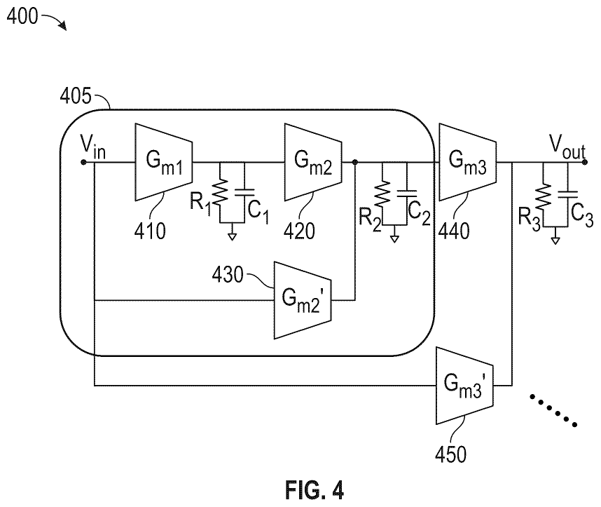

For example, it is possible to provide an N-stage feedforward compensation structure having multiple feedforward components. Referring now to FIG. 4, shown is a schematic diagram of a feedforward compensation structure in accordance with another embodiment. In FIG. 4, circuit 400 has a feedforward compensation structure as described above with regard to FIG. 3 (generally shown in block 405; however the components of block 405 are enumerated with the ‘400’ series, rather than the ‘300’ series of FIG. 3). As further shown in FIG. 4, there is an additional main path transconductor 440 (Gₘ₃) and another feedforward transconductor 450 (G_{m3′}) coupled between the input to the first main path transconductor 410 and an output of third main path transconductor 440.

With this arrangement, there are three poles and two zeros, as a zero introduced by feedforward transconductor 450 cancels a pole of second main path transconductor 420. In general, this feedforward compensation structure can be extended to N stages in which there are N main path transconductors and N−1 feedforward transconductors. More generally, N stages may have a unity gain frequency according to:

$${ω}_{ugf} = \frac{{G}_{mN}}{{C}_{N}}$$

As described above in certain implementations, a current reuse arrangement may be realized to lower power consumption by current sharing by multiple transconductor stages. And with the configuration shown in FIG. 4, reduced power consumption may be realized in first transconductor 410 by splitting it into PMOS and NMOS halves with each half sharing current with the other. Similarly, transconductor 420 could be implemented as a NMOS-only structure while transconductor 430 could be implemented as a PMOS-only structure, with each structure sharing current with the other. Transconductors 440 and 450 are each split into P MOS and NMOS halves and each half is made to share current with the other half. This approach of implementing the feedforward compensated op-amp by either splitting a transconductor into PMOS/NMOS halves and sharing current between the two halves, or combining two transconductors into one current sharing path results in significant current savings.

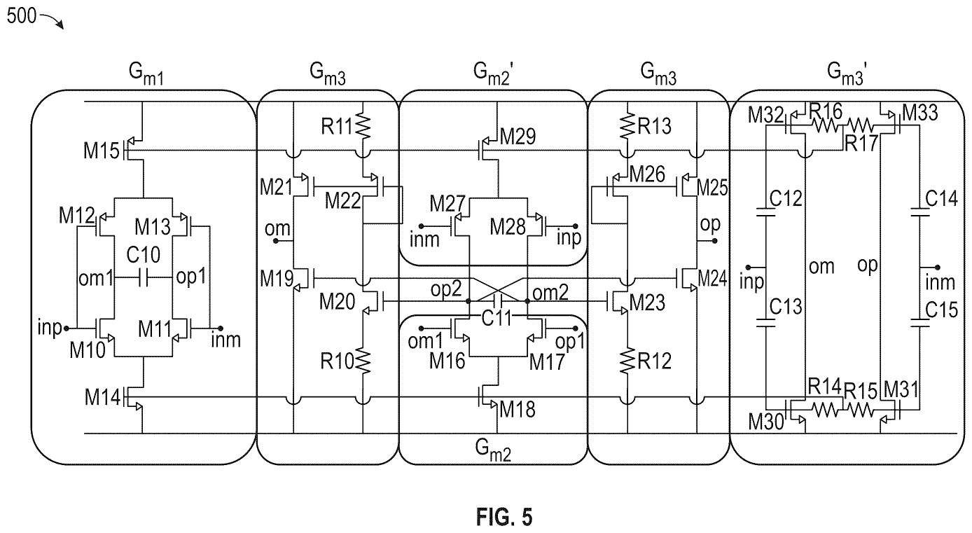

Referring now to FIG. 5, shown is a schematic diagram of a current reuse op-amp in accordance with an embodiment. As shown in FIG. 5, circuit 500 is implemented as a three-stage feedforward compensation op-amp having three main path transconductors (Gₘ₁-Gₘ₃) and two feedforward transconductors (G_{m2′}, G_{m3′}). With this arrangement, noise can be traded off while still maintaining high linearity, and internal poles/zeros can be designed to achieve a maximum loop gain at an interfering frequency.

In general, each transconductor is implemented with differential amplifiers. Referring in detail to transconductor Gₘ₁, NMOS devices M10, M11 and PMOS devices M12, M13 receive an incoming differential signal (inp, inm) and provide an amplified output signal (om1, om2) at their drain terminals. As shown, commonly coupled source terminals of NMOS devices M10, M11 couple to a reference current level via another NMOS device M14, and in turn, commonly coupled source terminals of PMOS devices M12, M13 couple to a supply voltage level via another PMOS device M15. Note presence of a capacitor C10 coupled between the drain terminals of NMOS devices M10-M13. In embodiments, capacitor C10 may be implemented as a tunable capacitance, which may be controlled to optimize performance based on a frequency of interest.

In turn, the output of transconductor Gₘ₁ couples to an input of transconductor Gₘ₂, namely to gate terminals of corresponding NMOS devices M16, M17, which amplify the signal and output the amplified signal (op2, om2) at drain terminals thereof. As shown, the drain terminals of NMOS devices M16, 17 couple to corresponding gate terminals of NMOS devices M19-20, M23-24 of additional main path transconductor Gₘ₃. Note presence of a capacitor C11 coupled between the drain terminals of NMOS devices M16-M17. In embodiments, capacitor C11 also may be implemented as a tunable capacitance.

The output of transconductor Gₘ₃ (namely, om, op, the output signal of op-amp 500) is provided via the commonly coupled drain terminals of PMOS devices M19, M24 and PMOS devices M21, M25. As shown, PMOS devices M21, M25 have commonly coupled gate terminals with PMOS devices M22, M26, which are diode-coupled devices that couple to a supply voltage node via resistors R11, R13 that couple to their source terminals. Note that this way of implementing the Gₘ₃ transconductor results in a Class-AB output stage for the op-amp, which in turns helps in achieving better linearity for a given current. As described earlier, current is further saved by implementing Gₘ₂ as a NMOS-only structure (formed of NMOS devices M16, M17 and M18) while G_{m2′} is implemented as a PMOS-only structure (formed of PMOS devices M27, M28 and M29) and G_{m2′} Shares the current with Gₘ₂. While it is shown in FIG. 5 that G_{m2′} is implemented as a PMOS structure and Gₘ₂ is implemented as a NMOS structure, it is to be understood that the vice versa is also possible (G_{m2′} implemented as a NMOS structure and Gₘ₂ as a PMOS structure). Current is saved in Gₘ₃ by splitting it into PMOS and NMOS halves. PMOS device M21 and NMOS device M19 thus share current with each other while PMOS device M25 shares current with NMOS device M24.

Still with reference to FIG. 5, a feedforward path includes a first feedforward transconductor G_{m2′} that is implemented with PMOS devices M27, M28. As shown, PMOS devices M27, M28 receive at their gate terminals the input signal and provide an amplified output signal at their drain terminals, commonly coupled to the drain terminals of NMOS devices M16, M17 of main path transconductor Gₘ₂ (and are thus also coupled to the input of main stage transconductor Gₘ₃). As further shown, the commonly coupled source terminals of PMOS devices M27, M28 couple via another PMOS device M29 to the supply voltage node.

Finally, with reference to feedforward transconductor G_{m3′}, a current reuse configuration is shown. More specifically, gate terminals of NMOS devices M30, M31 are coupled together via series resistors R14, R15, which generate a bias voltage used to bias NMOS devices M14, M18. Similarly, gate terminals of PMOS devices M32, M33 are coupled together via series resistors R16, R17, which generates a bias voltage used to bias PMOS devices M15, M29.

As further illustrated, the gate terminals of NMOS devices M30, M31 and PMOS devices M32, M33 receive the input signal via capacitive coupling through corresponding capacitors C12-C15, and output an amplified output signal to the same output path as main path transconductor Gₘ₃.

Note that with the configuration of the output stage of op-amp 500, the output signal can swing rail-to-rail. In this way, linearity is improved, particularly at higher power levels near a saturation level. Specifically, both transconductors Gₘ₃ and G_{m3′} swing rail-to-rai, with transconductor Gₘ₃ serving as the output stage and transconductor G_{m3′} ensuring that the op-amp is adequately compensated even as the signal swings from one rail to the other. Although shown at this high level in the embodiment of FIG. 5, many variations and alternatives are possible.

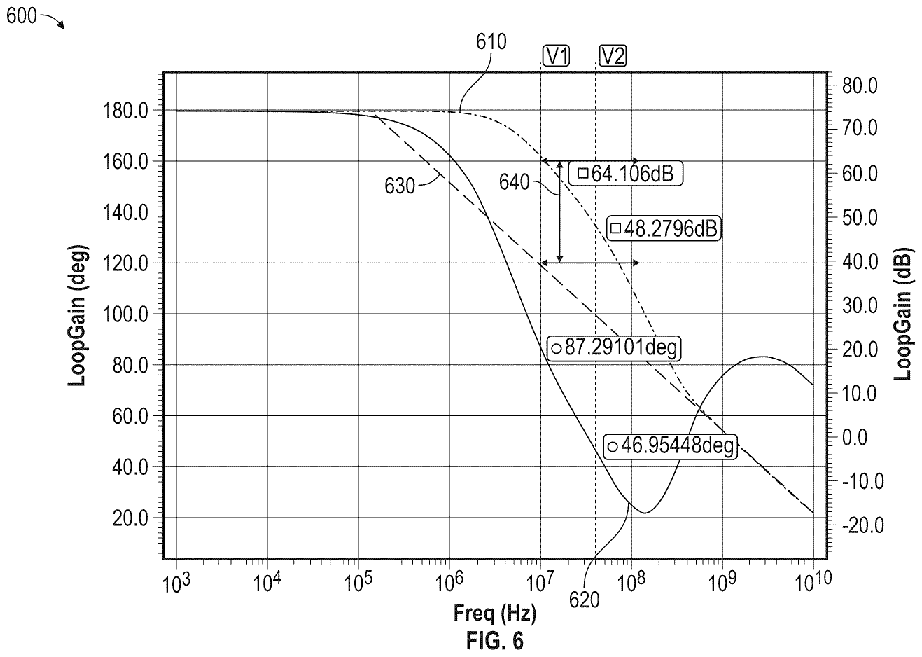

Referring now to FIG. 6, shown is a graphical illustration of loop gain realized using a feedforward compensated op-amp in accordance with an embodiment. More specifically as shown in FIG. 6, in graphical illustration 600 a loop gain of a feedforward compensated op-amp shown at curve 610 provides for greater loop gain at a lower UGF, as compared to a conventional Miller op-amp. In this regard, an equivalent loop gain is illustrated at curve 630 for such conventional Miller op-amp, which has a lower gain and would require a UGF of 16 GHz for an equivalent gain. Thus, a 24 dB greater loop gain (enumerated as 640) can be realized at 10 MHz using a feedforward compensated op-amp as described herein as compared to a Miller op-amp. While a Miller op-amp has a linear loop gain that remains on the 20 dB/decade line (including at a frequency of interest), by providing feedforward compensation structures for IF TIA and filters as described herein, better linearity and higher loop gain are realized, while achieving lower power consumption. Thus as shown at curve 610, loop gain using an embodiment is enhanced, optimizing gain versus UGF. At curve 620, a loop gain phase of a feedforward compensated op-amp is illustrated.

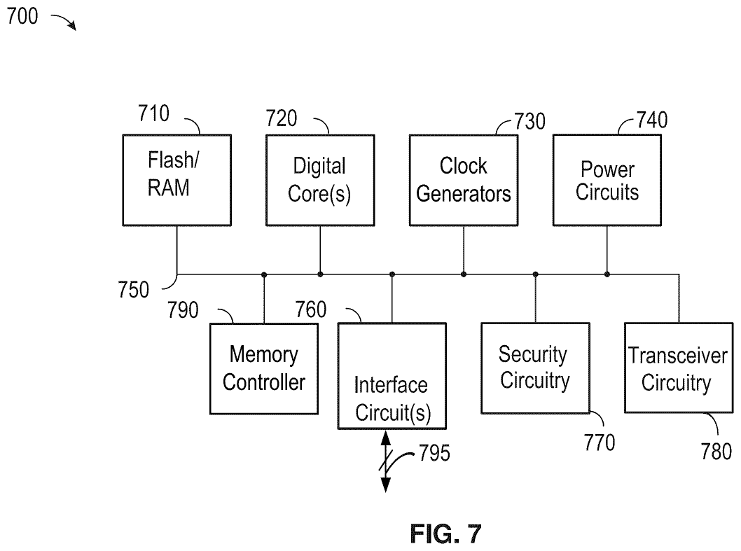

Referring now to FIG. 7, shown is a block diagram of a representative integrated circuit 700 that includes a wideband receiver architecture as described herein. In the embodiment shown in FIG. 7, integrated circuit 700 may be, e.g., a multi-mode wireless transceiver that may operate according to one or more wireless protocols or other device that can be used in a variety of use cases. In one or more embodiments, the circuitry of integrated circuit 700 shown in FIG. 7 may be implemented on a single semiconductor die or implemented on separate dies for wireless communication, MCU compute, external flash and/or other IP blocks needed to perform various functionalities.

Integrated circuit 700 may be included in a range of devices, but for purposes of discussion, it may be incorporated into an IoT device. In the embodiment shown, integrated circuit 700 includes a memory system 710 which in an embodiment may include volatile storage, such as RAM and non-volatile memory such as a flash memory. The flash memory is a non-transitory storage medium that can store instructions and data. Integrated circuit 700 also may include a memory controller 790.

Memory system 710 couples via a bus 750 to one or more digital cores 720, which may include one or more cores and/or microcontrollers that act as processing units of the integrated circuit. In turn, digital cores 720 may couple to clock generators 730 which may provide one or more phase locked loops or other clock generator circuitry to generate various clocks for use by circuitry of the IC.

As further illustrated, IC 700 further includes power circuitry 740. Additional circuitry may be present depending on particular implementation to provide various functionality and interaction with external devices. Such circuitry may include interface circuitry 760 which provides a digital communication interface with additional circuitry (such as another IC that can couple to IC 700 via a link 795). IC 700 also may include security circuitry 770 to perform wireless security techniques.

In addition, as shown in FIG. 7, transceiver circuitry 780 may be provided to enable transmission and reception of wireless signals, e.g., according to one or more of a local area or wide area wireless communication scheme, such as Matter, Zigbee, Bluetooth, IEEE 802.11, IEEE 802.15.4, cellular communication or so forth. Transceiver circuitry 780 may include at least one wideband receiver having a single-ended common gate LNA, along with RF and IF TIAs implemented using op-amps having feedforward compensation structures as described herein. Understand while shown with this high level view, many variations and alternatives are possible.

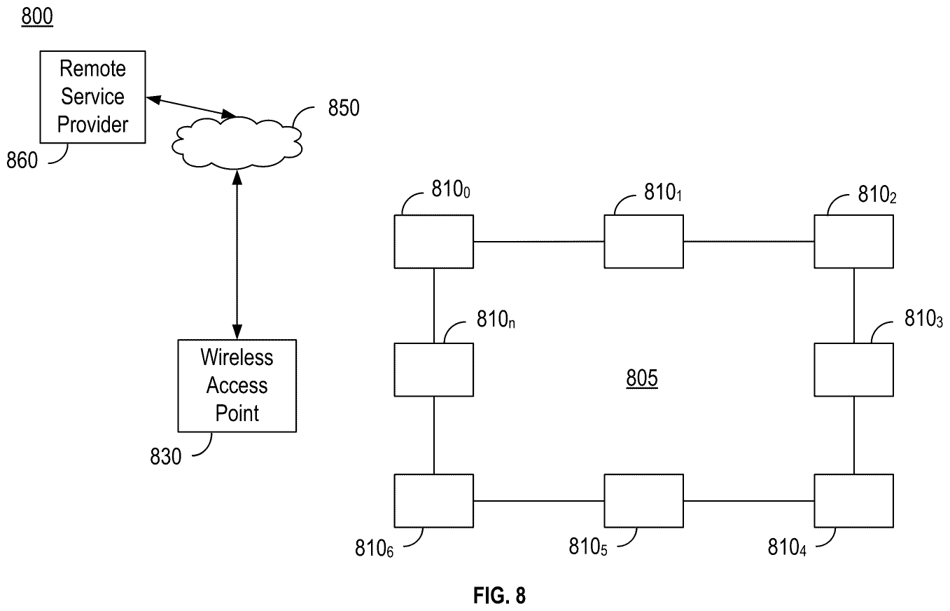

ICs such as described herein may be implemented in a variety of different devices as described above. Referring now to FIG. 8, shown is a high level diagram of a network in accordance with an embodiment. As shown in FIG. 8, a network 800 includes a variety of devices, including IoT and other wireless devices that may include wideband receiver architectures as described herein.

In the embodiment of FIG. 8, a wireless mesh network 805 is present, e.g., in a building having multiple wireless devices 810₀₋ₙ. As shown, wireless devices 810, which may be IoT or other wireless devices, couple to an access point 830 that in turn communicates with a remote service provider 860 via a wide area network 850, e.g., the Internet. Understand while shown at this high level in the embodiment of FIG. 8, many variations and alternatives are possible.

While the present disclosure has been described with respect to a limited number of implementations, those skilled in the art, having the benefit of this disclosure, will appreciate numerous modifications and variations therefrom. It is intended that the appended claims cover all such modifications and variations.

What is claimed is:

1. An apparatus comprising:
a first operational amplifier (op-amp) having a first feedforward compensation structure, the first op-amp to receive a first current and output a first voltage; and
a second op-amp having a second feedforward compensation structure, the second op-amp to receive a second current based on the first voltage and output a second voltage, wherein the first op-amp is to operate with a first current consumption and the second op-amp is to operate with a second current consumption, the second current consumption lower than the first current consumption.

2. The apparatus of claim 1, wherein the first op-amp comprises a transimpedance amplifier (TIA) to receive the first current at a downconverted frequency and to output the first voltage at the downconverted frequency.

3. The apparatus of claim 2, further comprising a filter coupled to the TIA, the filter comprising the second op-amp to receive the second current at the downconverted frequency.

4. The apparatus of claim 3, wherein the filter comprises a biquadratic filter further comprising a third op-amp having a third feedforward compensation structure, the third op-amp to receive a third current based on the second voltage and output a third voltage.

5. The apparatus of claim 3, wherein the first op-amp is to operate with a first noise performance level and the second op-amp is to operate with a second noise performance level, the second noise performance level higher than the first noise performance level.

6. The apparatus of claim 1, wherein the first op-amp comprises:
a plurality of transconductors; and
at least one feedforward transconductor coupled to at least some of the plurality of transconductors.

7. The apparatus of claim 6, wherein the at least one feedforward transconductor is to share current with at least one of the plurality of transconductors.

8. The apparatus of claim 6, wherein the plurality of transconductors comprises at least three main path transconductors, and the at least one feedforward transconductor comprises a first feedforward transconductor and a second feedforward transconductor.

9. The apparatus of claim 8, wherein the second feedforward transconductor is to provide compensation to at least one of the at least three main path transconductors as an output signal swings from a first rail to a second rail.

10. An apparatus comprising:
a feedforward compensated operational amplifier (op-amp) comprising:
a first main path transconductor;
a second main path transconductor coupled to the first main path transconductor; and
a feedforward path coupled between an input of the first main path transconductor and an output of the second main path transconductor, the feedforward path comprising at least one feedforward transconductor, wherein at least one of the first main path transconductor and the second main path transconductor is to reuse a current from the at least one feedforward transconductor.

11. The apparatus of claim 10, wherein the at least one feedforward transconductor is to cancel at least one pole of the first main path transconductor or the second main path transconductor.

12. The apparatus of claim 10, wherein the feedforward compensated op-amp comprises an intermediate frequency (IF) transimpedance amplifier (TIA) to receive an IF current and to output an IF voltage.

13. The apparatus of claim 12, further comprising a filter coupled to the IF TIA, the filter comprising:
a plurality of main path transconductors; and
at least one feedforward transconductor coupled between an input of a first main path transconductor of the plurality of main path transconductors and an output of a last main path transconductor of the plurality of main path transconductors.

14. The apparatus of claim 10, wherein the feedforward compensated op-amp further comprises:
a third main path transconductor coupled between the output of the first main path transconductor and an input of the second main path transconductor; and
the at least one feedforward transconductor comprises a first feedforward transconductor and a second feedforward transconductor.

15. The apparatus of claim 14, wherein an output of the second main path transconductor and an output of the second feedforward transconductor are to swing rail-to-rail.

16. The apparatus of claim 14, wherein the first feedforward transconductor is to share current with at least the third main path transconductor.

17. A method comprising:
receiving, in a first operational amplifier (op-amp) having a first feedforward compensation structure and operating with a first current consumption, a first current and outputting a first voltage; and
receiving, in a second op-amp having a second feedforward compensation structure and operating with a second current consumption lower than the first current consumption, a second current based on the first voltage and outputting a second voltage.

18. The method of claim 17, further comprising receiving the first current in the first op-amp comprising a transimpedance amplifier (TIA) at a downconverted frequency and outputting the first voltage at the downconverted frequency.

19. The method of claim 18, further comprising filtering the second current at the downconverted frequency, the second op-amp comprising a filter coupled to the TIA.

20. The method of claim 19, further comprising receiving, in a third op-amp having a third feedforward compensation structure, a third current based on the second voltage and outputting a third voltage.
